(19) United States
(12) Patent Application Publication
(10) Pub. No.: US 2012/0274366 A1
(43) Pub. Date: Nov. 1, 2012

(54) Integrated Power Stage

(75) Inventor: Michael A. Briere, Scottsdale, AZ (US)

(73) Assignee: INTERNATIONAL RECTIFIER CORPORATION, EL SEGUNDO, CA (US)

(21) Appl. No.: 13/454,039

(22) Filed: Apr. 23, 2012

Related U.S. Application Data
(60) Provisional application No. 61/480,058, filed on Apr. 28, 2011.

(51) Int. Cl. H03K 3/00

(52) U.S. Cl. 327/108

(57) ABSTRACT

In one implementation, an integrated power stage includes a common die situated over a load stage, the common die includes a driver stage and power switches. The power switches include a control transistor and a sync transistor. A drain of the control transistor receives an input voltage of the common die on one side (e.g., on a top surface) of the common die. A source of the control transistor is coupled to a drain of the sync transistor and provides an output voltage of the common die on an opposite side (e.g., on a bottom surface) of the common die. An interposer may be included under the power stage and includes an output inductor and optionally an output capacitor coupled to the output voltage of the common die on the opposite side of the common die.

### RELATED APPLICATIONS

The present application claims the benefit of and priority to pending U.S. provisional patent application No. 61/480,058, entitled “Integrated Vertical Power Converter,” filed on Apr. 28, 2011, which is hereby incorporated fully by reference into the present application.

In addition, each of the following U.S. patent documents is hereby incorporated by reference in its entirety into the present application:

U.S. Pat. No. 7,863,877;

U.S. Pat. No. 7,902,809;

U.S. Pat. No. 7,839,131;

U.S. Pat. No. 7,745,849;

U.S. Pat. No. 7,759,699;

U.S. Pat. No. 7,382,001;

U.S. Pat. No. 7,112,830;

U.S. Pat. No. 7,456,442;

U.S. Pat. No. 7,339,205;

U.S. Pat. No. 6,849,882;

U.S. Pat. No. 6,617,060;

U.S. Pat. No. 6,649,287;

U.S. Pat. No. 5,192,987;

U.S. Pat. No. 7,915,645;

U.S. Pat. No. 6,611,002;

U.S. Pat. No. 7,233,028;

U.S. Pat. No. 7,566,913;

U.S. Pat. No. 8,148,964;

U.S. patent application Ser. No. 11/999,552;

U.S. patent application Ser. No. 12/587,964;

U.S. patent application Ser. No. 12/928,103;

U.S. patent application Ser. No. 12/174,329;

U.S. patent application Ser. No. 12/928,946;

U.S. patent application Ser. No. 11/531,508;

U.S. patent application Ser. No. 13/021,437;

U.S. patent application Ser. No. 13/017,970;

U.S. patent application Ser. No. 12/653,097;

U.S. patent application Ser. No. 12/195,801;

U.S. patent application Ser. No. 12/211,120;

U.S. patent application Ser. No. 11/857,113;

U.S. patent application Ser. No. 11/999,552;

U.S. patent application Ser. No. 12/250,713;

U.S. patent application Ser. No. 13/397,190;

U.S. patent application Ser. No. 13/405,180.

### DEFINITION

As used herein, the phrases “III-nitride,” “III-nitride material” and similar terms refer to a compound semiconductor that includes nitrogen and at least one group III element including aluminum (Al), gallium (Ga), indium (In), and boron (B), and including but not limited to any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)}AsₐP_{b}N_{(1-a-b)}), for example. III-nitride material also refers generally to any polarity including but not limited to Ga-polar, N-polar, semi-polar or non-polar crystal orientations. III-nitride material may also include Wurtzitic, Zincblende or mixed polytypes, and single-crystal, monocrystalline, polycrystalline, or amorphous structures.

### BACKGROUND

A power conversion circuit can include a controller stage, a driver stage, and power switches, which may be operatively coupled to deliver power to a load stage. The controller and driver stages can be used to control the power switches and the power switches can be used to provide power to the load stage. The controller stage may be a separate chip or may be integrated into the driver stage or the load stage. The power conversion circuit should be designed to reduce or eliminate parasitics that negatively impact performance of the power conversion circuit. For example, the controller stage, the driver stage, the power switches, and the load stage should be connected so as to avoid long and non-linear connections that can introduce parasitics, such as parasitic resistance, inductance and capacitance. However, the physical arrangement of the controller stage, the driver stage, the power switches and the load stage can limit reduction of parasitics in the power conversion circuit.

### SUMMARY

The present disclosure is directed to an integrated power stage, substantially as shown in and/or described in connection with at least one of the figures, and as set forth more completely in the claims. In some implementations, the integrated power stage receives an input voltage on one side (e.g. a top side) of the integrated power stage and provides an output voltage on an opposite side (e.g. a bottom side) of the integrated power stage.

### BRIEF DESCRIPTION OF THE DRAWINGS

FIG. 1 presents an exemplary functional diagram of an integrated power stage, according to an implementation disclosed in the present application.

FIG. 2A presents an exemplary cross-sectional view of an integrated power stage, according to an implementation disclosed in the present application.

FIG. 2B presents an exemplary cross-sectional view of an integrated power stage, according to an implementation disclosed in the present application.

FIG. 3A presents an exemplary cross-sectional view of an integrated power stage, according to an implementation disclosed in the present application.

FIG. 3B presents an exemplary cross-sectional view of an integrated power stage, according to an implementation disclosed in the present application.

FIG. 4A presents an exemplary cross-sectional view of an integrated power stage, according to an implementation disclosed in the present application.

FIG. 4B presents an exemplary cross-sectional view of an integrated power stage, according to an implementation disclosed in the present application.

FIG. 5A presents an exemplary cross-sectional view of an integrated power converter arrangement, according to an implementation disclosed in the present application.

FIG. 5B presents an exemplary cross-sectional view of an integrated power converter arrangement, according to an implementation disclosed in the present application.

### DETAILED DESCRIPTION

The following description contains specific information pertaining to implementations in the present disclosure. One skilled in the art will recognize that the present disclosure may be implemented in a manner different from that specifically discussed herein. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

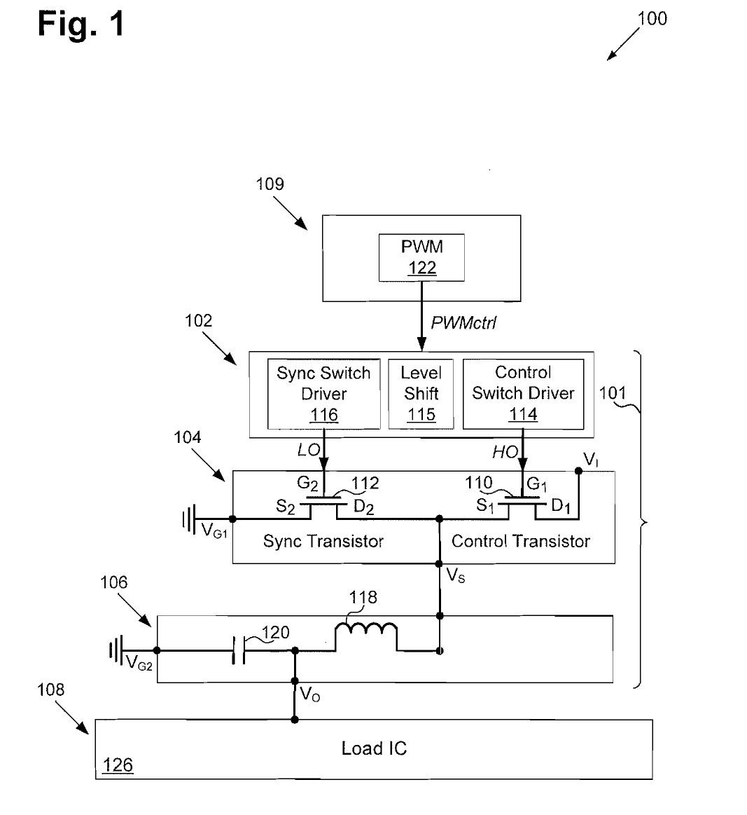

FIG. 1 presents an exemplary functional diagram of an integrated power stage, according to an implementation disclosed in the present application. In FIG. 1, diagram 100 includes integrated power stage 101 (which can also be referred to as integrated power stack 101) having driver stage 102, power switches 104, and interposer 106. Diagram 100 shows load stage 108 coupled to integrated power stage 101. Additionally, diagram 100 shows controller stage 109 coupled to integrated power stage 101.

Power switches 104 include control transistor 110 and sync transistor 112. Control transistor 110 includes source S₁, drain D₁, and gate G₁. Sync transistor 112 includes source S₂, drain D₂, and gate G₂. In the present implementation, control transistor 110 and sync transistor 112 are arranged in a half-bridge connected between input voltage V_{I} and ground voltage V_{G1} with output voltage V_{S}. In some implementations, input voltage V_{I} is a high voltage input, such as a high voltage supply rail input. Furthermore, ground voltage V_{G1} can be, for example, coupled to a low voltage or ground voltage supply rail. Also, output voltage V_{S} can be a low voltage output.

Also in the present implementation, control transistor 110 and sync transistor 112 are each III-Nitride transistors, such as III-Nitride field-effect transistors (FETs) or III-Nitride high electron mobility transistors (HEMTs). Thus, control transistor 110 is a III-Nitride control transistor and sync transistor 112 is a III-Nitride sync transistor. However, in some implementations, control transistor 110 and/or sync transistor 112 are not III-Nitride transistors.

In certain implementations, control transistor 110 and sync transistor 112 include one or more III-Nitride devices and/or group IV devices. In some implementations control transistor 110 and sync transistor 112 arc configured in a cascode configuration. In other implementations, control transistor 110 and sync transistor 112 are each HEMTs, for example III-Nitride HEMTs. In various implementations, any combination of control transistor 110 and sync transistor 112 can be E-mode (enhancement mode) or D-mode (depletion mode) devices.

In some implementations, driver stage 102 (e.g. control transistor 110 and sync transistor 112) is on a silicon substrate, for example, as discussed in U.S. Pat. No. 7,745,849 issued on Jun. 29, 2010 titled “Enhancement Mode III-Nitride Semiconductor Device with Reduced Electric Field Between the Gate and the Drain,” U.S. Pat. No. 7,759,699 issued on Jul. 20, 2010 titled “III-Nitride Enhancement Mode Devices,” U.S. Pat. No. 7,382,001 issued on Jun. 3, 2008 titled “Enhancement Mode III-Nitride FET,” U.S. Pat. No. 7,112,830 issued on Sep. 26, 2006 titled “Super Lattice Modification of Overlying Transistor,” U.S. Pat. No. 7,456,442 issued on Nov. 25, 2008 titled “Super Lattice Modification of Overlying Transistor,” U.S. Pat. No. 7,339,205 issued on Mar. 4, 2008 titled “Gallium Nitride Materials and Methods Associated with the Same,” U.S. Pat. No. 6,849,882 issued on Feb. 1, 2005 titled “Group-III Nitride Based High Electron Mobility Transistor (HEMT) with Barrier/Spacer Layer,” U.S. Pat. No. 6,617,060 issued on Sep. 9, 2003 titled “Gallium Nitride Materials and Methods,” U.S. Pat. No. 6,649,287 issued on Nov. 18, 2003 titled “Gallium Nitride Materials and Methods,” U.S. Pat. No. 5,192,987 issued on Mar. 9, 1993 titled “High Electron Mobility Transistor with GAN/ALXGA1-XN Heterojunctions,” U.S. Pat. No. 8,084,785 issued Dec. 27, 2011 titled “III-Nitride Power Semiconductor Device Having a Programmable Gate,” U.S. patent application Ser. No. 12/587,964 filed on Oct. 14, 2009 titled “Group III-V Semiconductor Device with Strain-relieving Interlayers,” U.S. patent application Ser. No. 12/928,946 filed on Dec. 21, 2010 titled “Stress Modulated Group III-V Semiconductor Device and Related Method,” U.S. patent application Ser. No. 11/531,508 filed on Sep. 13, 2006 titled “Process for Manufacture of Super Lattice Using Alternating High and Low Temperature Layers to Block Parasitic Current Path,” U.S. patent application Ser. No. 13/021,437 filed on Feb. 4, 2011 titled “Programmable III-Nitride Transistor with Aluminum-Doped Gate,” U.S. patent application Ser. No. 13/017,970 filed on Jan. 31, 2011 titled “Enhancement Mode III-Nitride Transistors with Single Gate Dielectric Structure,” U.S. patent application Ser. No. 12/653,097 filed on Dec. 7, 2009 titled “Gated AlGaN/GaN Heterojuction Schottky Device,” U.S. patent application Ser. No. 12/195,801 filed on Aug. 21, 2008 titled “Enhancement Mode III-Nitride Device with Floating Gate and Process for Its Manufacture,” U.S. patent application Ser. No. 12/211,120 filed on Sep. 16, 2008 titled “III-Nitride Semiconductor Device with Reduced Electric Field Between Gate and Drain and Process for Its Manufacture,” U.S. provisional patent application No. 61/447,479 filed on Feb 28, 2011 titled “III-Nitride Heterojunction Devices, HEMTs and Related Device Structures,” and U.S. provisional patent application No. 61/449,046 filed on Mar. 3, 2011 titled “III-Nitride Material Interlayer Structures.”

In the present implementation, driver stage 102 includes control switch driver 114 providing gate signal HO to control transistor 110 and sync switch driver 116 providing gate signal LO to sync transistor 112. Additionally, driver stage 102 may include other components including level shift 115, driver transistors, logic and protection circuitry, and may also include PWM circuitry. Driver stage 102 can include semiconductor switches, and can be, for example, silicon (Si) based (or more generally group IV based), III-Nitride based, or any combination thereof. In some implementations, for example, as discussed in U.S. Pat. No. 7,863,877 filed on Dec. 4, 2007 titled “Monolithically Integrated III-Nitride Power Converter,” driver stage 102 is integrated on a common die with power switches 104. However, in some implementations, driver stage 102 is on a separate die from power switches 104. Similarly, controller stage 109 can be on a separate die, or may be integrated on a common die with driver stage 102 or in some implementations, integrated on a common die with load stage 108.

In some implementations, for example, where control transistor 110 and sync transistor 112 are D-mode devices, driver stage 102 can be provided in accordance with any of U.S. Pat. No. 7,902,809 issued on Mar. 8, 2011 titled “DC/DC Converter Including a Depletion Mode Power Switch,” and U.S. Pat. No. 7,839,131 issued on Nov. 23, 2010 titled “Gate Driving Scheme for Depletion Mode Devices in Buck Converters.”

In certain implementations, integrated power stage 101 includes interposer 106. However in certain other implementations, interposer 106 is not required. FIG. 1 shows load stage 108 receiving output voltage V_{S} of power switches 104 through interposer 106 as interposer output V_{O}. As one example, input voltage V_{I} can be approximately 12 volts and interposer output V_{O} can be approximately 1.5 volt or less. As other examples, input voltage V_{I} can be approximately 8 volts or greater, 24 volts or greater, or 48 volts or greater. Interposer 106 can include one or more output inductors, such as output inductor 118, and in some implementations, can also include one or more output capacitors, such as output capacitor 120. As shown in FIG. 1, output inductor 118 is coupled between output voltage V_{S} and load stage 108. Also shown in FIG. 1, output capacitor 120 is coupled between output inductor 118 and ground voltage V_{G2}, which can be, for example, coupled to ground voltage V_{G1}. However, in some implementations, interposer 106 does not include output capacitor 120. Interposer 106 can include, for example, one or more interposing materials that may include ferrite or other magnetic material.

In diagram 100, load stage 108 can include, for example, load integrated circuit (IC) 126. In some implementations, load IC 126 includes a central processing unit (CPU), a microprocessor, a graphics processing unit (GPU), a memory IC, a memory array, and/or other circuits. Also, in some implementations, pulse width modulation (PWM) driver 122 (e.g. controller stage 109) is included in load IC 126, for example, as described in U.S. Pat. No. 7,863,877. FIG. 1 shows PWM driver 122 providing PWMctrl signal to driver stage 102.

In diagram 100, driver stage 102, power switches 104, interposer 106, and load stage 108 should be designed to reduce or eliminate parasitics that negatively impact performance. For example, driver stage 102, power switches 104, interposer 106, and load stage 108 should be connected so as to avoid long and non-linear connections that can introduce parasitics, such as parasitic resistance, inductance and capacitance. However, the physical arrangement of driver stage 102, power switches 104, interposer 106, and load stage 108 can limit reduction of parasitics in a power conversion circuit. Various implementations described in the present application offer flexibility in the physical arrangement allowing for, for example, reduction of parasitics. In various implementations, for example, input voltage terminal V_{I} is situated on one side (e.g. on a top surface) of integrated power stage 101, and output voltage terminal V_{S} (or interposer output V_{O} if interposer 106 is present) is situated on an opposite side (e.g.on a bottom surface) of integrated power stage 101.

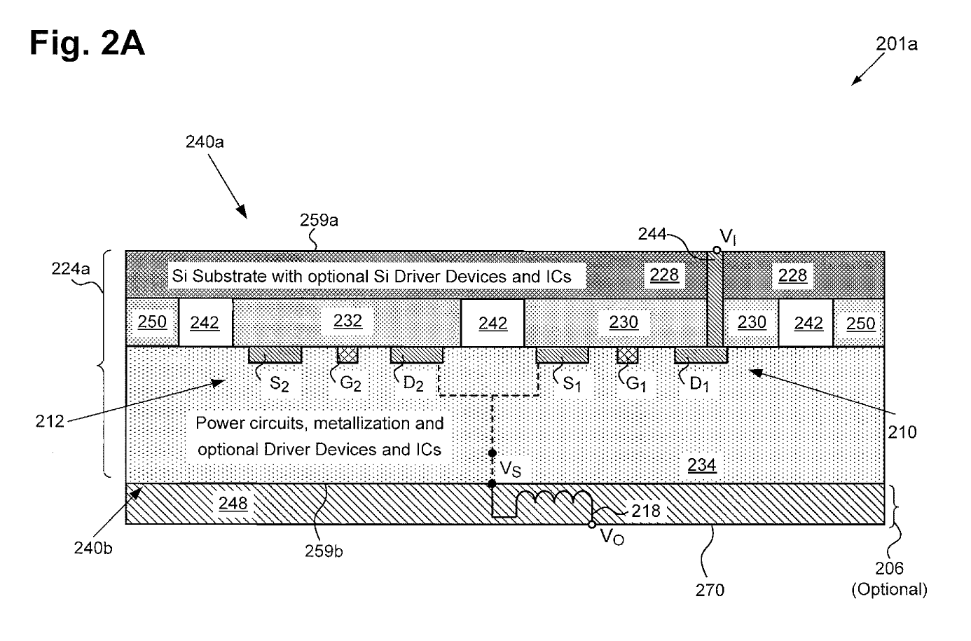

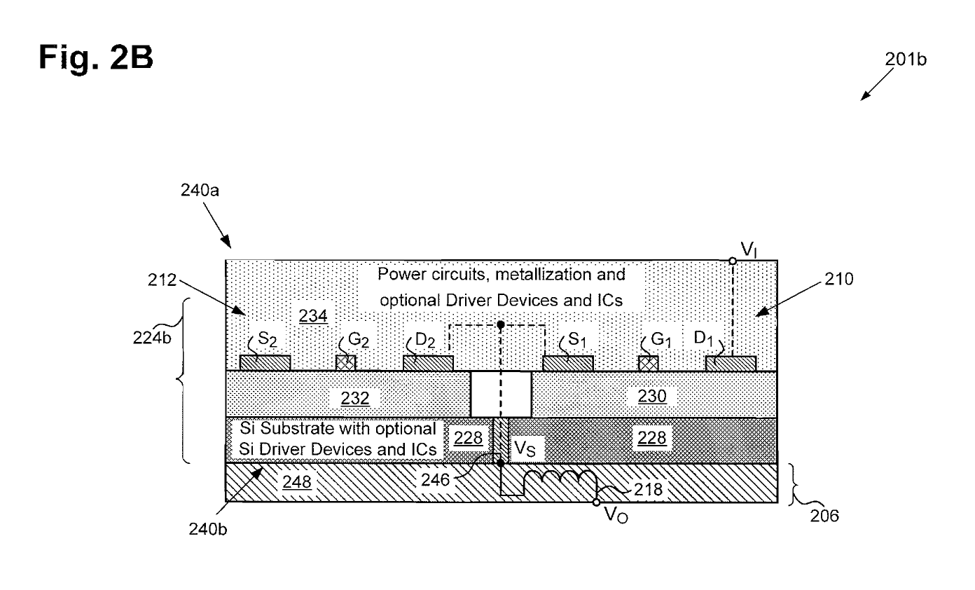

FIG. 2A presents an exemplary cross-sectional view of an integrated power stage, according to an implementation disclosed in the present application. More particularly, FIG. 2A presents integrated power stage 201a corresponding to integrated power stage 101 in FIG. 1.

Integrated power stage 201a includes common die 224a. Integrated power stage 201a also includes interposer 206. In integrated power stage 201a, common die 224a is situated over interposer 206. Common die 224a includes power switches 104 of FIG. 1. For example, common die 224a includes control transistor 210 and sync transistor 212 corresponding to control transistor 110 and sync transistor 112 in FIG. 1. FIG. 1 shows common die 224a including input voltage V_{I} situated on side 240a (more specifically on top surface 260a) and output voltage V_{S} situated on side 240b (more specifically on bottom surface 259b) of common die 224a, corresponding to input voltage V_{I} and output voltage V_{S} in FIG. 1. Common die 224a also has ground voltage V_{G1} of FIG. 1 (not shown in FIG. 2A). Common die 224a further includes substrate 228, control transistor body 230, sync transistor body 232, metallization region 234 (e.g. III-Nitride wafer frontside metallization region 234), and isolation regions 242.

In the present implementation, control transistor 210 and sync transistor 212 are III-Nitride devices. Also in the present implementation, control transistor 210 and sync transistor 212 are on substrate 228 of common die 224a. More particularly, control transistor body 230 and sync transistor body 232 are on substrate 228. In some implementations, control transistor 210 and sync transistor 212 are grown on substrate 228, which can be a silicon (Si) substrate or another type of substrate, such as a semiconductor substrate (e.g., a group IV or a sapphire substrate). Source S₁, Drain D₁, and gate G₁ of control transistor 210 are situated on side 240b of common die 224a. Similarly, source S₂, drain D₂, and gate G₂ of sync transistor 212 are situated on side 240b of common die 224a. Control transistor 210 and sync transistor 212 have active regions isolated by one of isolation regions 242, which can include dielectric material. In some implementations, isolation regions 242 include a trench. Isolation regions 242 can also include conductive material so long as the active regions of control transistor 210 and sync transistor 212 or other regions are sufficiently isolated (for implementations that include isolation regions 242).

As shown in FIG. 2A, also in the present implementation, common die 224a includes driver stage 102 of FIG. 1. Thus, driver stage 102 is monolithically integrated with power switches 104 in common die 224a. Control switch driver 114 and sync switch driver 116 are coupled to gates G₁ and G₂ respectively, for example, through control transistor body 230 and sync transistor body 232.

In the present implementation, driver stage 102 is on or in substrate 228 and includes Si devices, as shown in FIG. 2A. As noted above, while in the present implementation, substrate 228 is a Si substrate, substrate 228 can be a different type of substrate, including a different type of semiconductor substrate. Furthermore, substrate 228 can include different types of devices than the Si devices for driver stage 102. Additionally, driver stage 102 can be included in different portions of common die 224a than substrate 228. For example, driver stage 102 can be completely or partially in epi material 250 (e.g. III-Nitride epi material 250) and/or can be partially in or on substrate 228. Non-limiting examples are disclosed in U.S. Pat. No. 7,915,645 issued on Mar. 29, 2011 titled “Monolithic Vertically Integrated Composite Group III-V and Group IV Semiconductor Device and Method for Fabricating Same.”

While in the present implementation, common die 224a includes driver stage 102, in other implementations, driver stage 102 is separate from common die 224a. For example, in some implementations a driver stage die includes driver stage 102 and is situated over common die 224a. However, including driver stage 102 in common die 224a can allow for reduced parasitics as well as reduced size for integrated power stage 201a.

In integrated power stage 201a, drain D₁ of control transistor 210 is receiving input voltage V_{I} of common die 224a on side 240a of common die 224a. There are many ways in which this can be accomplished. For example, a through semiconductor via (TSV) and/or a through-wafer via (TWV) can be utilized. In the present implementation, common die 224a includes input via 244 (which is an input TSV in the present implementation) receiving input voltage V_{I} of common die 224a on side 240a of common die 224a, input via 244 may pass through substrate 228, epi material 250, and/or control transistor body 230, as examples. In the present implementation, input via 244 is coupled to drain D₁ of control transistor 210 and is passing through substrate 228 and control transistor body 230. This may be accomplished using, for example, various methods disclosed in U.S. Pat. No. 6,611,002 issued on Aug. 26, 2003 titled “Gallium Nitride Material Devices and Methods Including Backside Vias,” U.S. Pat. No. 7,233,028 issued on Jun. 19, 2007 titled “Gallium Nitride Material Devices and Methods of Forming the Same,” U.S. Pat. No. 7,566,913 issued on Jul. 28, 2009 titled “Gallium Nitride Material Devices Including Conductive Regions and Methods Associated with the Same,” U.S. patent application Ser. No. 12/928,103 filed on Dec. 3, 2010 titled “Monolithic Integration of Silicon and Group III-V Devices,” and U.S. patent application Ser. No. 12/174,329 filed on Jul. 16, 2008 titled “III-Nitride Device.”

In other implementations, drain D₁ of control transistor 210 is receiving input voltage V_{I} of common die 224a on side 240a of common die 224a utilizing conductive silicon or a group IV substrate for substrate 228. In some implementations, drain D₁ of control transistor 210 is coupled to input voltage V_{I} on the backside of a conductive substrate 228 (which is top surface 259a of common die 224a in the present implementation). For example, input via 244 can pass through control transistor body 230 and extend from drain D₁ of control transistor 210 to contact substrate 228 (e.g., a conductive substrate), or input via 244 can pass through epi material 250 and be electrically connected through topside conductors from drain D₁ of control transistor 210 to contact substrate 228. However, some implementations do not include input via 244.

Also in integrated power stage 201a, source S₁ of control transistor 210 is coupled to drain D₂ of sync transistor 212 and is providing output voltage V_{S} of common die 224a on side 240b (and more specifically bottom surface 259b) of common die 224a. This can be accomplished using various means and is represented by dashed lines in FIG. 2A. For example, any combination of conductive vias, layers, and other interconnects can be used, represented within metallization region 234. FIG. 2A shows output voltage V_{S} on bottom surface 259b of common die 224a. Bottom surface 259b of common die 224a can be, for example, a surface of control transistor body 230 and sync transistor body 232 or elements thereon.

Thus, as described above, drain D₁ of control transistor 210 is receiving input voltage V_{I} of common die 224a on side 240a (e.g. on top surface 259a) of common die 224a. Furthermore, source S₁ of control transistor 210 is coupled to drain D₂ of sync transistor 212 and is providing output voltage V_{S} of common die 224a on side 240b (e.g. on bottom surface 259b)of common die 224a. Utilizing such an arrangement offers flexibility in the physical arrangement of driver stage 102, power switches 104, and interposer 106 in FIG. 1, which can allow for, for example, reduction of parasitics.

Also in FIG. 2A, interposer 206 includes output inductor 218, corresponding to output inductor 118 in FIG. 1. Output inductor 218 is coupled to output voltage V_{S} of common die 224a on side 240b (e.g. on bottom surface 259b) of common die 224a. Interposer 206 can take various forms. In the implementation shown in FIG. 2A, for example, output voltage V_{S} of common die 224a is coupled to interposer 206, which includes interposer material 248. Interposer 206, is on side 240b (and bottom surface 259b) of common die 224a. Interposer material 248 can include a ferritic, or more generally, a magnetic film. In some implementations interposer material 248 is monolithically integrated with power switches 104 and is deposited onto bottom surface 259b, completely covering bottom surface 259b of common die 224a. In other implementations, interposer material 248 partially, covers bottom surface 259b of common die 224a. Interposer material 248 can be, for example, approximately 0.5 mm thick. In some implementations, interposer material 248 is greater than or equal to approximately 1.0 mm thick. The thickness of interposer material 248 can be selected based on a function of power switches 104 and conditioning or filtering desired at interposer output V_{O} to load stage 108. In some implementations, additional layers (e.g. a magnetic film) or discrete elements (e.g., an output capacitor) are integrated with interposer material 248 (e.g. a magnetic film) to assist in filtering or conditioning interposer output V_{O}.

Referring now to FIG. 2B, FIG. 2B presents an exemplary cross-sectional view of integrated power stage 201b, according to an implementation disclosed in the present application. Integrated power stage 201b is similar to integrated power stage 201a in FIG. 2A. However, integrated power stage 201b has a different orientation. In integrated power stage 201b, source S₁, drain D₁, and gate G₁ of control transistor 210 are situated on side 240a of common die 224b. Similarly, source S₂, drain D₂, and gate G₂ of sync transistor 212 are situated on side 240a of common die 224b. Integrated power stage 201b does not have input via 244 receiving input voltage V_{I} of common die 224b on side 240a of common die 224b. Rather, integrated power stage 201b includes output via 246 (which is an output TSV in the present implementation) providing output voltage V_{S} of common die 224b on side 240b of common die 224b. Output via 246 is situated between control transistor 210 and sync transistor 212 in the present example.

In some implementations, output via 246 extends through one of isolation regions 242. In other implementations, output via 246 extends through epi material 250 or control transistor body 230 and/or sync transistor body 232. In some implementations, output via 246 extends completely though common die 224b. In one implementation, output via 246 extends to contact substrate 228, which is a conductive substrate. For example, output via 246 can extend through epi material 250 or through control transistor body 230 and/or sync transistor body 232. However, some implementations do not include output via 246.

As described above with respect to FIG. 1, interposer 106 can include one or more output inductors, such as output inductor 118, and in some implementations, can also include one or more output capacitors, such as output capacitor 120. FIGS. 2A and 2B show one approach to providing interposer 106. Additional approaches are described below.

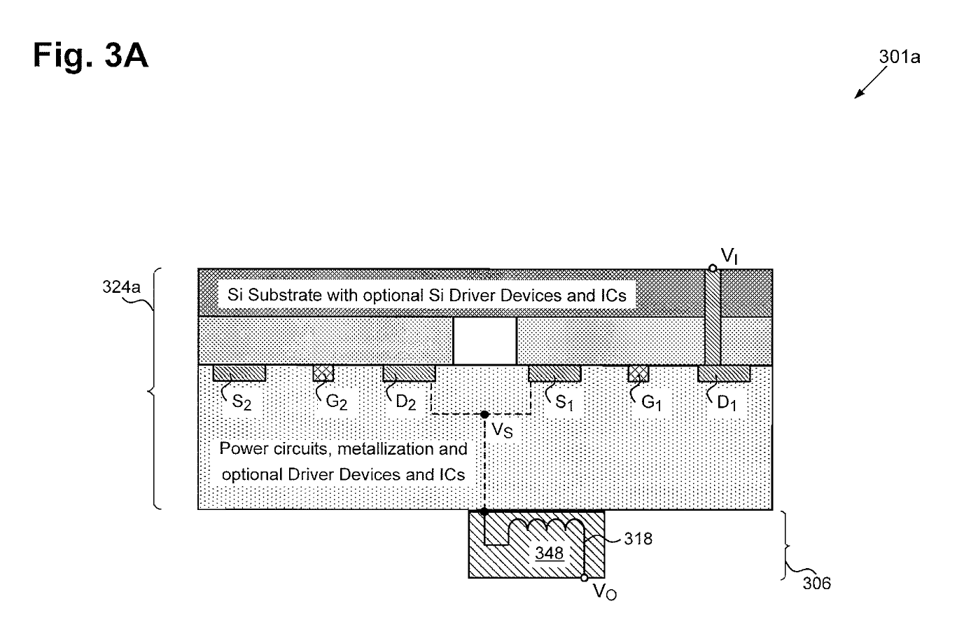

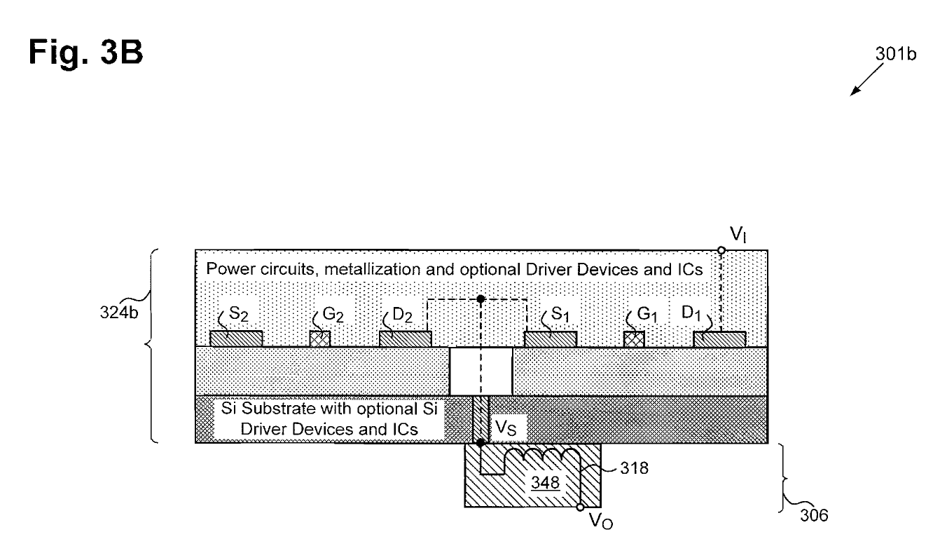

Now referring to FIG. 3A, FIG. 3A presents an exemplary cross-sectional view of integrated power stage 301a, according to an implementation disclosed in the present application. Integrated power stage 301a includes common die 324a corresponding to common die 224a in FIG. 2A.

Integrated power stage 301a also includes interposer 306. Interposer 306 includes output inductor 318 corresponding to output inductor 118 in FIG. 1. In integrated power stage 301a, interposer 306 forms lumped element or discrete inductor 348. In some implementations, additional discrete elements are utilized to complete filtering of output voltage V_{S} prior to coupling to load stage 108. The discrete magnetic elements can be connected to common die 324a utilizing solder balls or other approaches (not shown in FIG. 3A).

Turning to FIG. 3B, FIG. 3B presents an exemplary cross-sectional view of integrated power stage 301b, according to an implementation disclosed in the present application. FIG. 3B shows integrated power stage 301b including interposer 306. Integrated power stage 301b includes common die 324b corresponding to common die 224b in FIG. 2B.

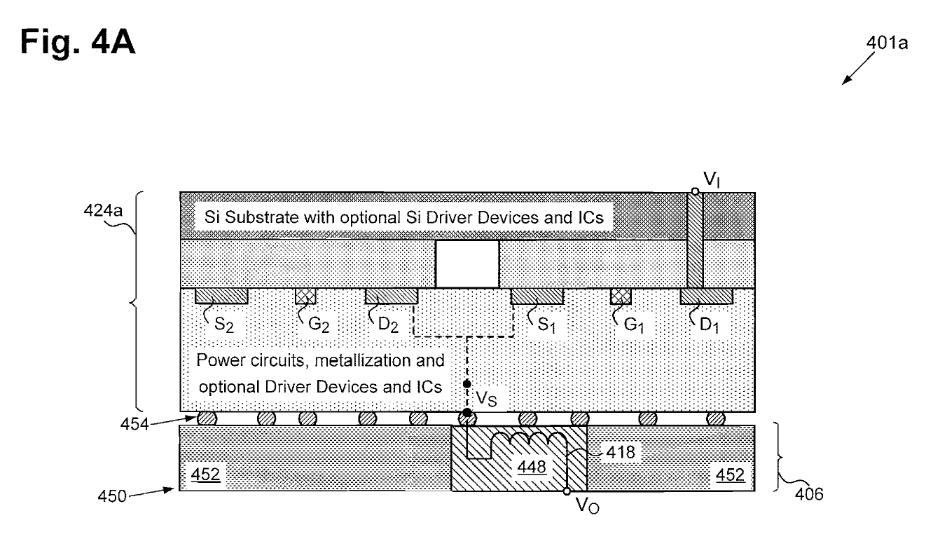

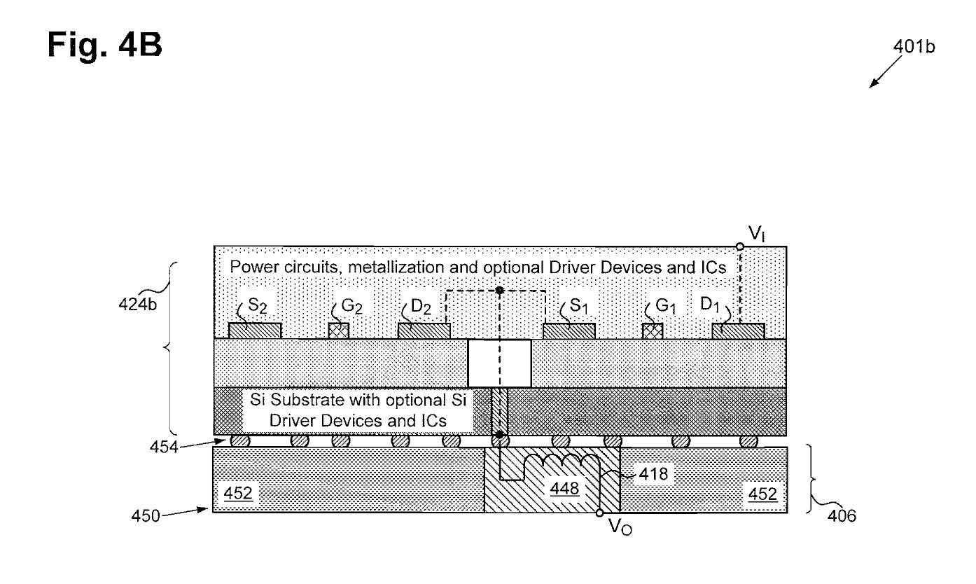

Now referring to FIG. 4A, FIG. 4A presents an exemplary cross-sectional view of integrated power stage 401a, according to an implementation disclosed in the present application. Integrated power stage 401a includes common die 424a corresponding to common die 224a in FIG. 2A.

Integrated power stage 401a also includes interposer 406. Interposer 406 includes output inductor 418 corresponding to output inductor 118 in FIG. 1. In integrated power stage 401a, interposer 406 includes interposer die or interposer substrate 450. One example of interposer die 450 is disclosed in U.S. patent application Ser. No. 12/250,713 filed on Oct. 14, 2008 titled “Interposer for an Integrated DC-DC Converter.” In the present implementation, interposer 406 can be formed using ferritic or other magnetic elements (or other materials forming a composite interposer) integrated or embedded into any suitable dielectric material 452. For example, FIG. 4A shows lumped element or discrete inductor 448, which can correspond to lumped element or discrete inductor 348 in FIG. 3A. Interposer 406 can also include additional components not shown in FIG. 4A, for example an output capacitor. Interposer die 450 can be connected to common die 424a, for example, using solder balls 454 or various other approaches.

In some implementations, interposer output V_{O} is coupled to load stage 108. Filtered power from interposer output V_{O} can be coupled to load stage 108 using various approaches. For example, in some implementations, interposer die 450 (or lumped element or discrete inductor 348 or interposer material 248) includes an interposer output contact (e.g. interposer output pad) located on a surface of interposer die 450 (or lumped element or discrete inductor 348 or interposer material 248). In one implementation, the interposer output contact is located on a surface of lumped element or discrete inductor 448, for example, on an inductor). The surface can be a top, bottom, and/or side surface.

Referring to FIG. 4B, FIG. 4B presents an exemplary cross-sectional view of integrated power stage 401b, according to an implementation disclosed in the present application. FIG. 4B shows integrated power stage 401b including interposer 406. Integrated power stage 401b includes common die 424b corresponding to common die 224b in FIG. 2B.

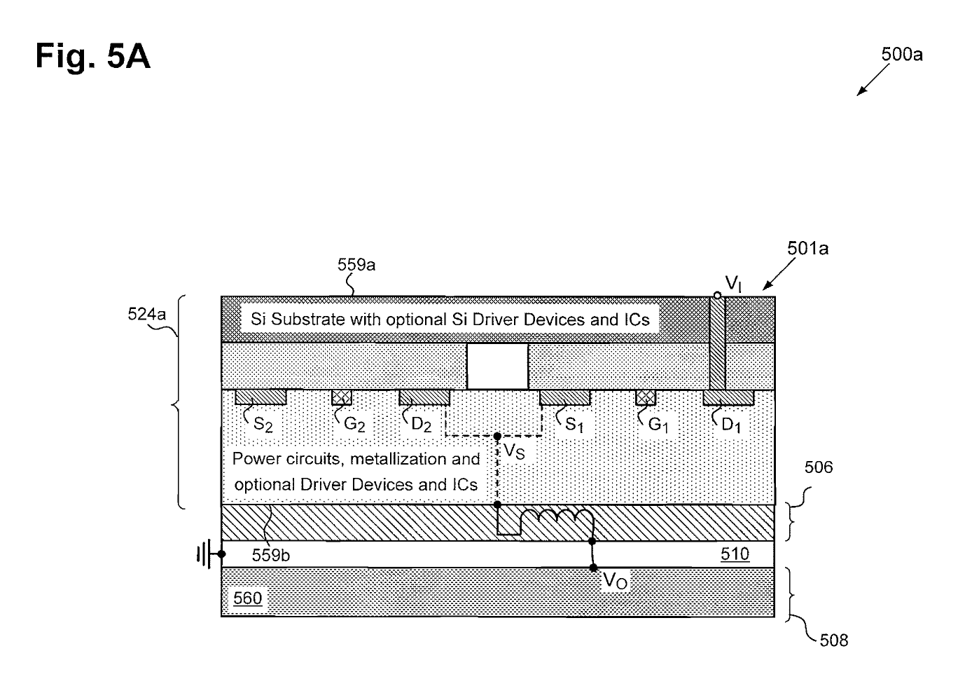

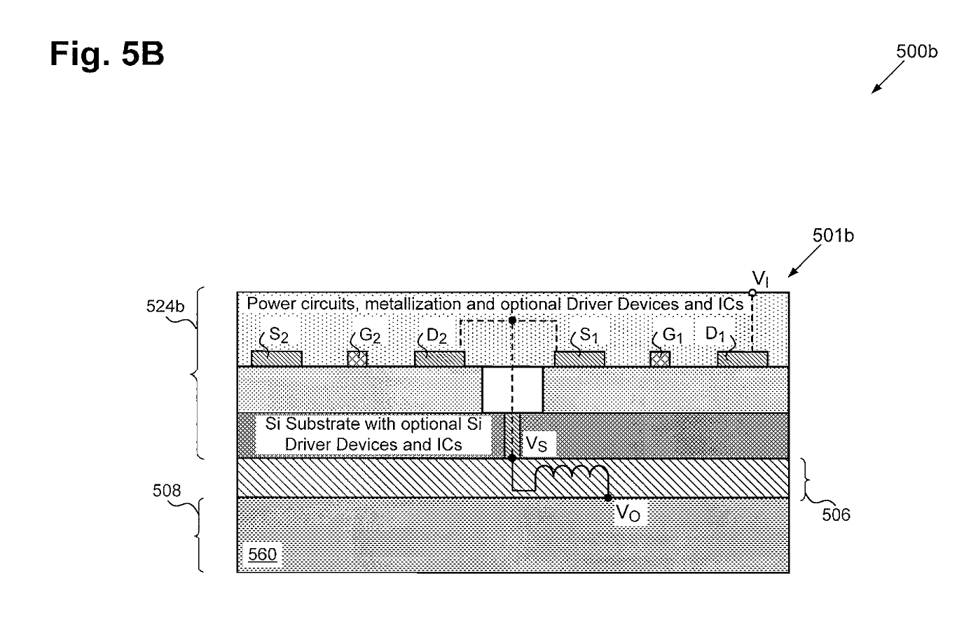

Referring to FIG. 5A, FIG. 5A presents an exemplary cross-sectional view of integrated power converter arrangement 500a, according to an implementation disclosed in the present application. In FIG. 5A, integrated power stage 501a includes common die 524a and interposer 506 corresponding respectively to common die 224a and interposer 206 in FIG. 2A. While in the present implementation, interposer 506 corresponds to interposer 206 in FIG. 2A, in other implementations, interposer 506 can correspond to any of interposers 306 and 406. Furthermore, interposer 506 can include additional components, such as an output inductor and or an output capacitor. Also in FIG. 5A, load stage 508 corresponds to load stage 108 in FIG. 1.

In the implementation shown in FIG. 5A, interposer 506 is situated over load stage 508. For example, interposer 506 can be over a top surface of load stage 508. In the arrangement shown, input voltage V_{I} enters one side of integrated power stage 501a (e.g. top surface 559a of common die 524a) and output voltage V_{S} exits common die 524a through an opposite side (e.g., bottom surface 559b of common die 524a) and enters a top side/surface of interposer 506. In this example, dielectric layer or film 510 is optionally formed between interposer 506 and load die 560. With dielectric layer 510 grounded, dielectric layer 510 functionally forms an output capacitor (with interposer 506 and load stage 508) with interposer output V_{O} entering a top side/surface of load stage 508, which can include, for example, load die 560 having a load IC. In the present implementation, integrated power converter arrangement 500a can be referred to as an integrated power converter package.

Turning to FIG. 5B, FIG. 5B presents an exemplary cross-sectional view of integrated power converter arrangement 500b, according to an implementation disclosed in the present application. In FIG. 5B, integrated power stage 501b includes common die 524b and interposer 506 corresponding respectively to common die 224b and interposer 206 in FIG. 2B. While in the present implementation, interposer 506 corresponds to interposer 206 in FIG. 2A, in other implementations, interposer 506 can correspond to any of interposers 306 and 406 and can include an output capacitor, for example, similarly formed by dielectric layer or film 510 in FIG. 5A. Similar to FIG. 5A, FIG. 5B shows load stage 508 corresponding to load stage 108 in FIG. 1.

Various implementations of the present disclosure result in highly integrated power converters with reduced parasitics, such as reduced parasitic resistance, inductance and capacitance. From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the spirit and the scope of those concepts. As such, the described implementations are to be considered in all respects as illustrative and not restrictive. It should also be understood that the present application is not limited to the particular implementations described herein, but many rearrangements, modifications, and substitutions are possible without departing from the scope of the present disclosure.

1. An integrated power stage comprising:
a common die comprising a driver stage and power switches, said power switches including a control transistor and a sync transistor;
a drain of said control transistor receiving an input voltage of said common die on one side of said common die;
a source of said control transistor coupled to a drain of said sync transistor and providing an output voltage of said common die on an opposite side of said common die.

2. The integrated power stage of claim 1, further comprising an interposer that includes an output inductor.

3. The integrated power stage of claim 1, further comprising an interposer that includes an output inductor and an output capacitor.

4. The integrated power stage of claim 1, wherein said source of said control transistor and said drain of said sync transistor are situated on said one side of said common die.

5. The integrated power stage of claim 1, wherein said source of said control transistor and said drain of said sync transistor are situated on said opposite side of said common die.

6. The integrated power stage of claim 1 comprising an input via receiving said input voltage of said common die on said one side of said common die.

7. The integrated power stage of claim 1, comprising an output via providing said output voltage of said common die on said opposite side of said common die.

8. The integrated power stage of claim 1, wherein a gate of said control transistor and a gate of said sync transistor are situated on said one side of said common die.

9. The integrated power stage of claim 1, wherein a gate of said control transistor and a gate of said sync transistor are situated on said opposite side of said common die.

10. The integrated power stage of claim 1, further comprising an interposer including an output inductor,wherein a load stage is coupled to said output inductor and said interposer is situated over said load stage.

11. The integrated power stage of claim 1, wherein said input voltage is approximately 8 volts or greater.

12. The integrated power stage of claim 1, further comprising an interposer that includes an output inductor and an interposer output that is approximately 1.5 volts or less.

13. The integrated power stage of claim 1 further comprising an interposer that includes an output inductor, said output inductor coupled to a load stage, said load stage including a central processing unit (CPU), a microprocessor, a graphics processing unit (GPU), or a memory array.

14. The integrated power stage of claim 1 wherein said driver stage includes a level shifter, a control switch driver, and a sync switch driver.

15. An integrated power stage comprising:
a common die situated over a load stage, said common die comprising a driver stage and power switches, said power switches including a III-Nitride control transistor and a III-Nitride sync transistor;
a drain of said III-Nitride control transistor receiving an input voltage of said common die on one side of said common die;
a source of said III-Nitride control transistor coupled to a drain of said III-Nitride sync transistor and providing an output voltage of said common die on an opposite side of said common die.

16. The integrated power stage of claim 15 comprising an interposer that includes an output inductor, said output inductor coupled to said output voltage of said common die on said opposite side of said common die.

17. The integrated power stage of claim 16 wherein said interposer includes an output capacitor.

18. The integrated power stage of claim 15, wherein said driver stage is on a silicon substrate.

19. The integrated power stage of claim 15, wherein said III-Nitride control transistor and said III-Nitride sync transistor are over a silicon substrate of said common die.

20. The integrated power stage of claim 15, wherein said source of said III-Nitride control transistor and said drain of said III-Nitride sync transistor are situated on said one side of said common die.

21. The integrated power stage of claim 15, wherein said source of said III-Nitride control transistor and said drain of said III-Nitride sync transistor are situated on said opposite side of said common die.

22. The integrated power stage of claim 15 comprising an input via receiving said input voltage of said common die on said one side of said common die.

23. The integrated power stage of claim 15, with an output via providing said output voltage of said common die on said opposite side of said common die.

24. The integrated power stage of claim 15, comprising an interposer that includes an output inductor, a load stage coupled to said output inductor and said interposer situated over said load stage.

25. The integrated power stage of claim 15, wherein said input voltage is approximately 8 volts or greater

26. The integrated power stage of claim 15, further comprising an interposer that includes an output inductor and an interposer output that is approximately 1.5 volts or less.

27. The integrated power stage of claim 15 comprising an interposer that includes an output inductor, a load stage coupled to said output inductor, said load stage includeing a central processing unit (CPU), a microprocessor, a graphics processing unit (GPU), or a memory array.

28. The integrated power stage of claim 15 wherein said driver stage includes a level shifter, a control switch driver, and a sync switch driver.
